(19) United States
(12) Patent Application Publication
(10) Pub. No.: US 2008/0007988 A1
(43) Pub. Date: Jan. 10, 2008

(54) Non-volatile memory device including variable resistance material and method of fabricating the same

(75) Inventors: Seung-Eon Ahn, Yongin-si (KR); Myoung-Jae Lee, Yongin-si (KR); Dong-Chul Kim, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/802,661

(22) Filed: May 24, 2007

(30) Foreign Application Priority Data
Jul. 10, 2006 (KR) 10-2006-0064457

(51) Int. Cl. G11C 11/24; H01L 21/00; H01L 21/20

(52) U.S. Cl. 365/148; 438/385; 257/E45.003

(57) ABSTRACT

Provided is a non-volatile memory device including a variable resistance material and method of fabricating the same. The non-volatile memory device may include a lower electrode, an intermediate layer on the lower electrode including one material selected from the group consisting of HfO, ZnO, InZnO, and ITO, a variable resistance material layer on the intermediate layer, and an upper electrode on the variable resistance material layer. A memory device having multi-level bipolar switching characteristics based upon the size of the device may be provided.

### PRIORITY STATEMENT

This application claims priority under 35 USC § 119 to Korean Patent Application No. 2006-0064457, filed on Jul. 10, 2006, in the Korean Intellectual Property Office (KIPO), the entire contents of which are herein incorporated by reference.

### BACKGROUND

1. Field

Example embodiments relate to a non-volatile memory device, which may have stable bipolar switching characteristics by inducing an indium tin oxide (ITO) layer and a NiO oxide layer between a lower electrode and an upper electrode, and method of fabricating the same.

2. Description of the Related Art

It is desirable that semiconductor memory devices operate at a higher speed and have a larger number of memory cells per unit area, which allows for a higher integration rate and operation at a lower power. As such, there has been an increasing progression of research on semiconductor memory devices.

Related semiconductor memory devices may include memory cells connected to one another in a circuit. For example, a unit memory cell of a dynamic random access memory (DRAM), which is a representative semiconductor memory device, may comprise one switch and one capacitor. The advantages of DRAM may include a higher integration rate and a faster operating speed. However, DRAM may have a disadvantage of stored data being lost after power is turned off.

Flash memory is representative of a non-volatile memory device in which stored data may be retained even after power turns off. However, flash memory may have disadvantages of a lower integration rate and a slower operating speed.

Non-volatile memory devices of which there has been a current progression of research may include magnetic random access memory (MRAM), ferroelectric random access memory (FRAM), phase-change random access memory (PRAM), and resistance random access memory (RRAM). RRAM may use a variable resistance property in which resistance varies according to the voltage of a transition metal oxide (TMO).

FIG. 1 illustrates a related RRAM device using a variable resistance material. A perovskite-based material or a transition metal oxide (TMO) may be used as the variable resistance material. A memory device using the perovskite-based material may have bipolar switching characteristics.

Referring to FIG. 1, the RRAM device may include a variable resistance material layer 11 and an upper electrode 12, which may be sequentially formed on a lower electrode 10. The lower electrode 10 and the upper electrode 12 may be formed of a general conductive material, for example, metal. The variable resistance material layer 11 may be formed of a perovskite-based material having a variable resistance property (e.g., STO(SrTiO₃) or PCMO(Pr_{0.3}Ca_{0.7}MnO₃)).

A high temperature process and/or an epitaxial growth may be needed to deposit the perovskite-based material used to form the variable resistance material layer 11. There may be difficulty in adjusting the composition for forming a ternary oxide. Accordingly, manufacturing costs may increase and/or manufacturing processes may become more difficult, thereby resulting in a lower yield.

### SUMMARY

Example embodiments provide a variable resistance non-volatile memory device with an improved electrode structure and method of fabricating the same. As such, the device may be easier to manufacture and may have a higher integration rate and more stable bipolar switching characteristics.

Example embodiments provide a non-volatile memory device including a variable resistance material. The device further includes a lower electrode, an intermediate layer on the lower electrode including one material selected from the group consisting of HfO, ZnO, InZnO, and ITO, a variable resistance material layer on the intermediate layer, and an upper electrode on the variable resistance material layer.

The variable resistance material layer may include a Ni oxide. The lower electrode may include one material selected from the group consisting of Pt, Ru, Ir, Ni, Co, Cr, W, and Cu (or an alloy thereof). The upper electrode may include one material selected from the group consisting of Pt, Ru, Ir, Ni, Co, Cr, W, and Cu (or an alloy thereof). The intermediate layer may be formed to a thickness of about 1-50 nm. The variable resistance material layer may be formed to a thickness of about 1-100 nm.

Example embodiments also provide a method of fabricating a non-volatile memory device including a variable resistance material. The method further includes forming a lower electrode, forming an intermediate layer on the lower electrode including one material selected from the group consisting of HfO, ZnO, InZnO, and ITO, forming a variable resistance material layer on the intermediate layer, and forming an upper electrode on the variable resistance material layer.

### BRIEF DESCRIPTION OF THE DRAWINGS

Example embodiments will be more clearly understood from the following detailed description taken in conjunction with the accompanying drawings. FIGS. 1-4 represent non-limiting, example embodiments as described herein.

FIG. 1 illustrates a related non-volatile memory device including a variable resistance material;

FIG. 2 illustrates a non-volatile memory device including a variable resistance material according to example embodiments;

FIG. 3 is a graph illustrating bipolar switching characteristics of the non-volatile memory device including the variable resistance material illustrated in FIG. 2; and

FIG. 4 is a graph of bipolar switching characteristics based upon the size of the non-volatile memory device including the variable resistance material illustrated in FIG. 2.

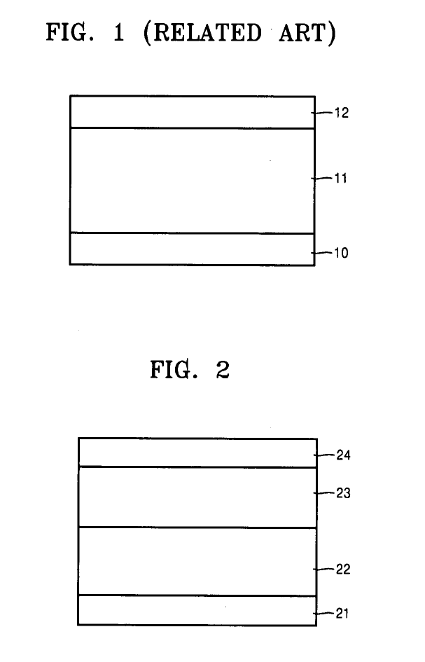

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 2 illustrates a non-volatile memory device including a variable resistance material according to example embodiments.

Referring to FIG. 2, the non-volatile memory device including the variable resistance material may include a lower electrode 21, an intermediate layer 22 on the lower electrode 21 including material selected from the group consisting of HfO, ZnO, InZnO, and ITO, a variable resistance material layer 23 on the intermediate layer 22, and an upper electrode 24 on the variable resistance material layer 23.

According to example embodiments, the lower electrode 21 and the upper electrode 24 may include a conductive material used for an electrode of a related semiconductor memory device (e.g. one material selected from the group consisting of Pt, Ru, Ir, Ni, Co, Cr, W, and Cu (or an alloy thereof)).

The intermediate layer 22 may include a material in which charge trapping may easily occur (e.g., one material selected from the group consisting of HfO, ZnO, InZnO, and ITO). ITO may comprise indium, tin, and oxide. The thickness of the intermediate layer 22 may not necessarily be limited but generally may be about 1-50 nm.

The variable resistance material layer 23 may include a Ni oxide. The property of the Ni oxide may be determined according to an oxygen partial pressure in a chamber when the Ni oxide is formed. When the oxygen partial pressure is less than approximately 5%, a Ni oxide having a metal property may be formed. When the oxygen partial pressure is between approximately 5% and 15%, a Ni oxide having a memory switching property may be formed. When the oxygen partial pressure is approximately equal to or greater than 15%, a Ni oxide having a threshold switching property may be formed. Example embodiments may be characterized in that the variable resistance material layer 23 may include the Ni oxide in the state in which the oxygen partial pressure is approximately equal to or greater than 15%. The variable resistance material layer 23 may be formed under an oxygen partial pressure of about 30%. The thickness of the variable resistance material layer 23 may not necessarily be limited but generally may be about 1-100 nm.

The non-volatile memory device including the variable resistance material illustrated in FIG. 2 may use a semiconductor device manufacturing process (e.g., physical vapor deposition (PVD) including sputtering, atomic layer deposition (ALD), and/or chemical vapor deposition (CVD)). A temperature required for forming a related bipolar switching device using a STO-based material may be equal to or greater than about 700° C. However, in the non-volatile memory device illustrated in FIG. 2, a temperature required for forming the non-volatile memory device may be equal to or less than about 350° C. Thus, the non-volatile memory device may be formed at a lower temperature.

The non-volatile memory device including the variable resistance material illustrated in FIG. 2 may be connected to a switching device, for example, a transistor and/or a diode. A gate structure may be formed on a semiconductor substrate including source and drain regions, for example, and the source or drain region may be connected to a lower electrode of the non-volatile memory device including the resistance variable material illustrated in FIG. 2. In addition, the source or drain region may be connected to a diode structure and may form a cross point type memory device.

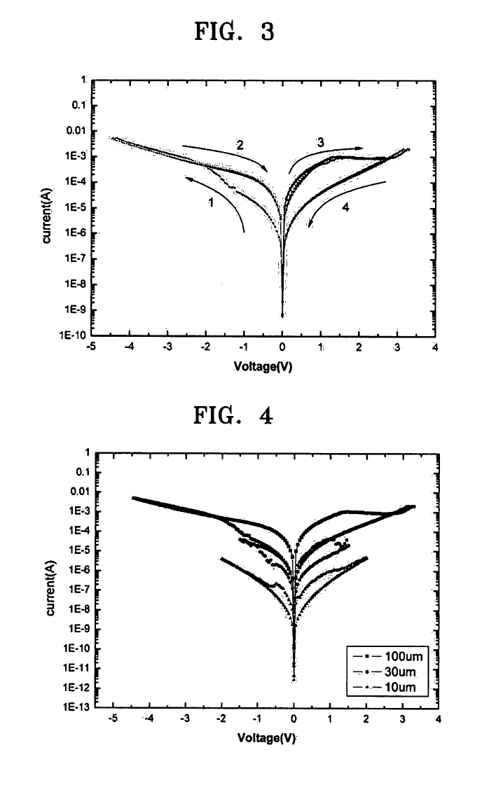

The non-volatile memory device including the variable resistance material illustrated in FIG. 2 has bipolar switching characteristics which will now be described in detail with reference to FIG. 3.

FIG. 3 is a graph illustrating bipolar switching characteristics of the non-volatile memory device including the variable resistance material illustrated in FIG. 2. In the graph of FIG. 3, the lower electrode 21 and the upper electrode 24 may include Pt, the intermediate layer 22 may include ITO, and the variable resistance material layer 23 may include a Ni oxide deposited under an oxygen partial pressure of about 30%. A specimen having a width and a length each of about 100 micrometers may be measured.

Referring to FIG. 3, when the voltage gradually decreases from 0V to a negative voltage in an initial state, current flowing through the variable resistance material layer 23 may gradually increase. When the applied voltage continuously decreases, the current may increase along line 1 of FIG. 3, for example. In example embodiments, an applied voltage down to about −4V is illustrated. Further, when the applied voltage increases, the current may be almost the same as the current of line 1 at about −2V. However, when the applied voltage increases from −2V to 0V, a variation in current from line 1 may occur along line 2. Consequently, the same applied voltages may have two resistances.

When the voltage gradually increases from 0V to a positive voltage, current flowing through the variable resistance material layer 23 may gradually increase. When the applied voltage continuously increases, the current may increase along line 3 of FIG. 3, for example. In example embodiments, an applied voltage up to about 3V is illustrated. Further, when the applied voltage decreases, a current similar to the current of line 3 may be obtained. However, when the applied voltage continuously decreases, the current may decrease and a current along line 4 that varies from the current of line 3 may be obtained. Consequently, even the applied positive voltages may have two resistances.

Referring to FIG. 3, when a positive and a negative voltage are applied to the non-volatile variable resistance memory device illustrated in FIG. 2, the voltages may have two resistances. The variable resistance memory device having the bipolar switching characteristics may be implemented using a Ni oxide (which indicates bipolar switching characteristics) and may be used in a traditional monopolar switching device.

FIG. 4 is a graph of bipolar switching characteristics based upon the size of the non-volatile memory device including the variable resistance material illustrated in FIG. 2. The specimens used in FIG. 4 may include a Pt lower electrode, an ITO layer, a variable resistance material layer including a Ni oxide, and a Pt upper electrode. The specimens may have the same thickness but may have different widths and lengths of about 100 micrometers, 30 micrometers and 10 micrometers, respectively.

Referring to FIG. 4, as the area of a device decreases, a smaller current based upon an applied voltage may be measured and the applied voltage region having two resistances may decrease. Even when the size of the device decreases, two resistances may be clearly classified so that the non-volatile memory device including the variable resistance material may be used as a memory device.

According to example embodiments, the non-volatile memory device including the variable resistance material may have a simpler structure, stable bipolar switching characteristics, a higher integration rate, and/or may be used as a cross point type memory device. In addition, the non-volatile memory device may be manufactured using a simpler process at a lower temperature than the related perovskite-based material may be manufactured.

Example embodiments may be connected to a transistor structure and/or may be used together with a diode. In addition, it may be obvious that example embodiments may be used in an array form of a cross point structure.

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of the claims. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A non-volatile memory device including a variable resistance material, the device comprising:
a lower electrode;
an intermediate layer;
a variable resistance material layer on the intermediate layer; and
an upper electrode on the variable resistance material layer.

2. The device of claim 1, wherein the intermediate layer includes one material selected from the group consisting of HfO, ZnO, InZnO, and ITO.

3. The device of claim 1, wherein the variable resistance material layer comprises a Ni oxide.

4. The device of claim 1, wherein the lower electrode includes one material selected from the group consisting of Pt, Ru, Ir, Ni, Co, Cr, W, and Cu (or an alloy thereof).

5. The device of claim 1, wherein the upper electrode includes one material selected from the group consisting of Pt, Ru, Ir, Ni, Co, Cr, W, and Cu (or an alloy thereof).

6. The device of claim 1, wherein the intermediate layer has a thickness of about 1-50 nm.

7. The device of claim 1, wherein the variable resistance material layer has a thickness of about 1-100 nm.

8. A method of fabricating a non-volatile memory device including a variable resistance material, the method comprising:
forming a lower electrode;
forming an intermediate layer;
forming a variable resistance material layer on the intermediate layer; and
forming an upper electrode on the variable resistance material layer.

9. The method of claim 8, wherein the intermediate layer includes one material selected from the group consisting of HfO, ZnO, InZnO, and ITO.

10. The method of claim 8, wherein the variable resistance material layer comprises a Ni oxide.

11. The method of claim 8, wherein the lower electrode includes one material selected from the group consisting of Pt, Ru, Ir, Ni, Co, Cr, W, and Cu (or an alloy thereof).

12. The method of claim 8, wherein the upper electrode includes one material selected from the group consisting of Pt, Ru, Ir, Ni, Co, Cr, W, and Cu (or an alloy thereof).

13. The method of claim 8, wherein the intermediate layer is formed to a thickness of about 1-50 nm.

14. The method of claim 8, wherein the variable resistance material layer is formed to a thickness of about 1-100 nm.
